(19) United States
(12) Patent Application Publication
(10) Pub. No.: US 2023/0307332 A1
(43) Pub. Date: Sep. 28, 2023

(54) Power Semiconductor Module and Method for Producing a Power Semiconductor Module

(71) Applicant: Siemens Aktiengesellschaft, Muenchen (DE)

(72) Inventors: Roland LORZ, Röttenbach (DE); Philipp KNEIßL, Nürnberg (DE)

(21) Appl. No.: 18/018,286

(22) PCT Filed: Jul. 27, 2021
(86) PCT No.: PCT/EP2021/070976

§ 371 Date: Jan. 27, 2023

(30) Foreign Application Priority Data
Jul. 30, 2020 (EP) 20188637

(51) Int. Cl. H01L 23/498; H01L 23/053; H01L 23/40; H01L 23/495

(52) U.S. Cl. CPC H01L 23/49811; H01L 23/053; H01L 23/4006; H01L 23/49551; H01L 23/49844

(57) ABSTRACT

A power semiconductor module includes a power semiconductor circuit and a housing partially surrounding the circuit that has a first and second contact electrodes which are each electrically conductively connected to the circuit and are each guided outwards through the housing through a hole in the housing, wherein the housing has first, second and third contacting regions, where the first and second contact electrodes are respectively contactable in the first and second contacting regions, the first and second contact electrodes are contactable together in the third contacting region, the housing has a recess in each contacting region, into which a threaded part is inserted, the recess and the threaded part receive a screw to contact the contact electrodes in each contacting region with an external voltage/current source on an outer face of the housing, and where the contact electrodes also have a recess for receiving the screw.

### CROSS-REFERENCE TO RELATED APPLICATIONS

This is a U.S. National Stage of Aapplication No. PCT/EP2021/070976 filed 27 Jul. 2021. Priority is claimed on European Application No. 20188637.1 filed 30 Jul. 2020 the content of which is incorporated herein by reference in its entirety.

### BACKGROUND OF THE INVENTION

### 1. Field of the Invention

The invention relates to a power semiconductor module, a housing for the power semiconductor module, a power semiconductor module system with a plurality of power semiconductor modules and a method for producing the power semiconductor module.

### 2. Description of the Related Art

Power semiconductors are generally packaged in housings. Particularly for higher powers, a number of semiconductors are integrated into a single housing to achieve higher currents. Often, the semiconductors of a “half-bridge” are integrated together in a housing to ensure low-inductance circuitry. Such a half-bridge housing can have three terminals (DC+, DC- and AC). Because the AC connection experiences a greater current load, it often has a duplicated or reinforced design. Furthermore, the DC- and DC+ terminals are in close proximity and can thus have a low inductance design.

The module housing must perform a number of tasks meaning that the effort involved in development and manufacture (injection molds, bending tools, and/or automation) is very high and therefore only profitable for high volumes.

The trend in power electronics is generally toward higher switching frequencies and at the same time lower system perturbation. 3L topologies are increasingly being used here, including for higher powers. 3L stands for ‘three level’ and means that the circuit can have three different voltage potentials on the AC output (for example, DC+, DC- and DCM).

For lower powers, pins (solder or press fit) are generally placed at the edge of the housing. If the module design is aimed at flexibility, the pins can be positioned relatively flexibly. The main disadvantages of these pins are their low current-carrying capacity and, at higher powers, the current flow across the PCB.

For higher powers, half-bridge modules are very frequently used. These quite often have three or four power connection terminals, as a rule screw terminals, in order to create a 2-level half-bridge within them as effectively as possible (in terms of complexity and costs). For a 3L half-bridge, the arrangement or the number of power terminals is not suitable. To nevertheless create a 3L half-bridge, a suitable new module housing must be constructed (major effort, high investment costs, low volumes).

Alternatively, the 3L half-bridge can be implemented in 2 module housings. For this, a module with midpoint switches is usually added to a 2L module. A major disadvantage of this is that the arrangement is not suitable for rapid switching, because each switching operation takes place between the two modules rather than within a module.

Many of the currently available module housings are suitable for 3L topologies only to a very limited extent due to their power connections. On the other hand, the volumes open to 3L modules are often not high enough to justify independent housing development.

EP 1 467 607 B1 discloses a power switch module with contact electrodes mounted on a housing of a power switch module.

WO 2017/216228 A1 discloses a power semiconductor circuit comprising a power semiconductor device for switching a load.

### SUMMARY OF THE INVENTION

It is an object of the invention is to provide a power semiconductor module that can be used in a variable manner in various configuration scenarios.

This and other objects and advantages are achieved in accordance with the invention by a power semiconductor module, a housing for a power semiconductor module and by a method for producing the power semiconductor module, where the power semiconductor module in accordance with the invention has a power semiconductor circuit and a housing that at least partially surrounds the power semiconductor circuit, and where the power semiconductor circuit has a first contact electrode and a second contact electrode, which are each electrically conductively connected to the power semiconductor circuit and which are each guided outward through the housing through a recess in the housing made for this purpose. The power semiconductor module is characterized in that the housing has a first, a second and a third contacting region, where the first contact electrode can be contacted in the first contacting region and the second contact electrode can be contacted in the second contacting region, and where the first contact electrode and the second contact electrode can be contacted together in the third contacting region.

The power semiconductor circuit can be used to control and switch electric currents of a comparatively high strength, such as more than 50 amperes. The power semiconductor circuit can comprise semiconductor elements, such as IGBTs (Insulated Gate Bipolar Transistor), MOSFETs (Metal Oxide Semiconductor Field Effect Transistors), thyristors, diodes and similar, arranged on a substrate, and which via a conductive layer of the substrate, together with bonding wires and/or a composite film, can be connected with each other electrically conductively. The semiconductor elements arranged on the substrate can be electrically connected to a single or to multiple half-bridge circuits, which are used, for example, for rectifying and inverting electric voltages and currents.

The tasks of a housing for a power semiconductor module can include the mechanical relief, guidance and insulation of the individual contact electrodes. In the context of the invention any housing can be used that at least partially surrounds the power semiconductor circuit, in order to perform the above functions among others.

The contact electrodes have the task of transmitting electric power to the semiconductor circuit. For this purpose, the contact electrodes are configured such that they can be electrically conductively connected with an external voltage/current source (for example, by soldering, welding or a mechanical connection such as crimping or screwing). To this end, the contact electrodes must at least in partial regions have a not inconsiderable electrical conductivity, to be able to transmit the power to the power semiconductor circuit. The contact electrodes can, for example, be made of copper, iron-nickel or electrically conductive silicon.

The power semiconductor module in accordance with the invention has a housing with at least three contacting regions. These are provided so that one of the two contact electrodes or both contact electrodes together can each be contacted in one of the contacting regions on the housing with a current/voltage source via, for example, of a current rail.

In each of the contacting regions, the housing has a recess to receive a screw, in order to contact the contact electrodes in each case in the contacting region, preferably on an outer face of the housing, with a current/voltage source by means of, for example, a current rail. Here, the contact electrodes preferably also have a corresponding recess to accommodate the screw. Comparable attachment options exist, but the screw connection is an established and well-suited method for connecting or contacting materials such as the contact electrodes. To secure the screw connection, the corresponding threaded part (arranged on an inner side of the housing) can be used. The threaded part can, for example, be a nut. In order to compensate for a tolerance, the recesses in the contact electrodes can each be configured as a longitudinally extended hole (known as an elongated hole).

If the two contact electrodes are both jointly contacted in the third contacting region, then the result is a single contact electrode with a cross section corresponding to the sum of the cross sections of the first and second contact electrodes. This more solid contact electrode can now have high electric currents passed through it.

If the two contact electrodes are contacted in the first or second contacting region with a current/voltage source via, for example, a current rail, then the result is two individual contact electrodes with a smaller cross section than previously described. These less solid contact electrodes can have lower currents, for example, with DC voltages DC+ and DC-, passed through them.

Various power semiconductor circuits can be realized with the invention, without having to change the configuration of the housing of the power semiconductor module, these having different requirements in terms of the number of contact electrodes and their effective cross section.

The invention allows a reduction in housing costs, because when the housing is produced the contact electrodes do not have to be integrated into the actual housing. The volumes of the actual housing that can be achieved may thus be greater, because this can be used flexibly in various applications.

It should be understood the power semiconductor module is not restricted to two contact electrodes and three contacting regions. Rather, this is a minimum configuration. Power semiconductor modules are possible that have an integer multiple of first and second contact electrodes and an integer multiple of three contacting regions. Accordingly, there can be, for example, four contact electrodes and six contacting regions, or six contact electrodes and nine contacting regions. Equally, further contact electrodes and/or contacting regions (in addition to those already referred to) may be present.

In a preferred embodiment of the invention, the first and second contact electrode (and any further contact electrodes present) can each be bent around two edges of the housing. The edges are preferably configured in the region of the recesses, through which the contact electrodes are each guided outward through the housing. In other words, the contact electrodes, which following the execution of the holes in the housing are, for example, configured vertically to an outer face of the housing, are bent into a “horizontal” position on the outer face of the housing. In the contacting regions, the contact electrodes bent there can be contacted with a current/voltage source via, for example, a current rail.

Advantageously, the edges have a rounding to facilitate bending of the contact electrodes around the edges. This can also prevent damage to the respective contact electrode from bending it around the respective edge.

In the region of the recesses in which the contact electrodes are guided outward through the housing, these can be surrounded by an electrically insulating material. This material can, for example, be injected into the recesses.

In the third contacting region, in which the first and the second contact electrode can be contacted, the housing preferably has a smaller thickness than in the first and the second contacting region. Preferably, the housing is configured such that a thickness of the housing in the third contacting region, in which the two contact electrodes can be contacted, is created so that when the two contact electrodes are arranged in the third contacting region a new (effective) thickness of the housing (including contact electrodes) results, which corresponds to the thickness of the housing in the first or second contacting region (in the case where the first or contact electrode is contacted there).

The cross sections of the first and second contact electrodes may differ from one another. Accordingly, the housing can have a thickness in the first contacting region that differs from the thickness in the second contacting region. The difference in the thickness of the housing (without contact electrodes) is preferably equal to the difference in the cross section of the two contact electrodes, so that the two thicknesses of the housing in the first and the second contacting region do not differ significantly from one another, if the two contact electrodes are contacted there.

The housing is particularly preferably configured substantially rectangular with four larger-area longitudinal sides and two smaller-area end faces, where the contacting regions are located in a central region of one of the four longitudinal sides. In other words, the contacting regions are arranged centrally in the housing. The advantages of this are as follows:
A symmetrical layout within the power semiconductor module is possible, which is particularly suitable for parallel circuits of semiconductor chips;
Within the power semiconductor module no long conductor structures develop, so that multiple power semiconductor modules connected in parallel have less influence on one another.

The above-mentioned objects and advantages are also achieved in accordance with the invention by a housing for a power semiconductor module, wherein the power semiconductor module is configured as explained above.

The objects and advantages are also achieved in accordance with the invention by a method for producing a power semiconductor module with the following method steps:
a) Producing a power semiconductor circuit;
b) Connecting a first contact electrode and a second contact electrode with the power semiconductor circuit, preferably via soldering or ultrasound welding;
c) Surrounding, at least partially, the power semiconductor circuit with a housing, where the first contact electrode and the second contact electrode are each guided outward through the housing through a recess in the housing, where the housing has a first, second and third contacting region, where in the first contacting region the first contact electrode and in the second contacting region the second contact electrodes can be contacted, and where in the third contacting region the first contact electrode and the second contact electrode can be contacted together.

In a further step, the first contact electrode is bent and in the first contacting region or in the third contacting region contacted with an external voltage/current source, and the second contact electrode is bent and contacted in the second contacting region or in the third contacting region, where the contacting each occur preferably with the aid of a screw.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The characteristics, features and advantages of this invention described above and the way in which these are achieved, will become clearer and easier to understand from the following description of exemplary embodiments, which are explained in more detail in conjunction with the drawings, in which:

FIG. 1 is a perspective view of a power semiconductor module in accordance with the invention in a first configuration mode;

FIG. 2 is a perspective view of the power semiconductor module of FIG. 1 in a second configuration mode;

FIG. 3 is a top view of the power semiconductor module of FIG. 1 in a third configuration mode;

FIG. 4 is a sectional view of a power semiconductor module in accordance with the invention;

FIG. 5 is a flowchart of the method in accordance with the invention.

### DETAILED DESCRIPTION OF THE EXEMPLARY EMBODIMENTS

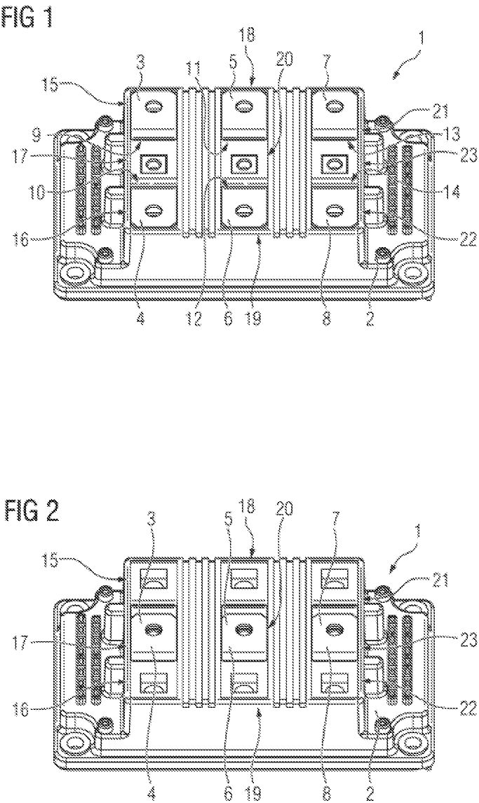

FIG. 1 shows a perspective view of a power semiconductor module 1 in accordance with the invention. The power semiconductor module 1 has a housing 2, which surrounds a power semiconductor circuit located within (not visible in FIG. 1). The power semiconductor circuit within the housing 2 has a first contact electrode 3, a second contact electrode 4, a third contact electrode 5, a fourth contact electrode 6, a fifth contact electrode 7 and a sixth contact electrode 8, which are electrically conductively connected with the power semiconductor circuit.

The contact electrodes 3, 4, 5, 6, 7, 8 are guided outward through the housing 2 through correspondingly configured recesses 9, 10, 11, 12, 13, 14. Once they have passed through the housing 2, the contact electrodes 3, 4, 5, 6, 7, 8 have been bent so that they rest substantially flat against an outer face of the housing 2. In each contact electrodes 3, 4, 5, 6, 7, 8, there is a circular recess, through which the screw can be guided, so as to contact the contact electrodes 3, 4, 5, 6, 7, 8 with an external voltage/current source.

The housing 2 has a first contacting region 15, a second contacting region 16, a third contacting region 17, a fourth contacting region 18, a fifth contacting region 19, a sixth contacting region 20, a seventh contacting region 21, an eighth contacting region 22 and a ninth contacting region 23.

In each of the contacting regions 15, 16, 17, 18, 19, 20, 21, 22, 23, the housing 2 has a recess in the form of a circular hole, in which a threaded part in the form of a nut can be or is inserted (not shown in FIG. 1).

In FIG. 1, the power semiconductor module 1 is configured in accordance with a first configuration mode. In this, the first contact electrode 3 is bent (upward in FIG. 1) around an edge in the housing 2 in the first contacting region 15 (see FIG. 4) and can be contacted by a screw (not shown) with an external voltage/current source (not shown) in the first contacting region 15. The second contact electrode 4 is bent downward in FIG. 1 and can be contacted by a screw (not shown) with an external voltage/current source (not shown) in the second contacting region 16. In the third contacting region 17, no contact electrode is present.

The third contact electrode 5 is bent upward in FIG. 1 and can be contacted by a screw (not shown) with an external voltage/current source (not shown) in the fourth contacting region 18. The fourth contact electrode 6 is bent downward in FIG. 1 and can be contacted by a screw (not shown) with an external voltage/current source (not shown) in the fifth contacting region 19. In the sixth contacting region 20 no contact electrode is present.

The fifth contact electrode 7 is bent upward in FIG. 1 and can be contacted by a screw (not shown) with an external voltage/current source (not shown) in the seventh contacting region 21. The sixth contact electrode 8 is bent downward in FIG. 1 and can be contacted by a screw (not shown) with an external voltage/current source (not shown) in the eighth contacting region 22. In the ninth contacting region 23, no contact electrode is present.

FIG. 2 shows the power semiconductor module 1 in accordance with the invention in a second configuration mode. Here, the first contact electrode 3 is bent (downward in FIG. 2) around an edge in the housing 2 in the third contacting region 17 (see FIG. 4) and can be contacted by a screw (not shown) with an external voltage/current source (not shown) in the third contacting region 17. The second contact electrode 4 is bent upward in FIG. 2 and can be contacted by a screw (not shown) together with the first contact electrode 3 with an external voltage/current source (not shown) in the third contacting region 17. In the first contacting region 15 and in the second contacting region 16, no contact electrodes are present. The overlaying of the first and second contact electrodes 3, 4 in the third contacting region 17 results in a new contact electrode, the cross section of which corresponds to the sum of the respective cross sections of the first and second contact electrodes 3, 4. This more solid electrode can transport the higher powers or currents to the power semiconductor circuit that are required in the second configuration mode.

In FIG. 2, the third contact electrode 5 is bent (downward in FIG. 2) around an edge in the housing 2 in the sixth contacting region 20 (see FIG. 4) and can be contacted by a screw (not shown) with an external voltage/current source in the sixth contacting region 20. The fourth contact electrode 6 is bent upward in FIG. 2 and can be contacted by a screw (not shown) together with the third contact electrode 5 with an external voltage/current source in the sixth contacting region 20. In the fourth contacting region 18 and in the fifth contacting region 21, no contact electrodes are contacted.

In FIG. 2, the fifth contact electrode 7 is in addition bent (downward in FIG. 2) around an edge in the housing 2 in the ninth contacting region 23 (see FIG. 4) and can be contacted by a screw (not shown) with an external voltage/current source in the ninth contacting region 23. The fifth contact electrode 7 is bent upward in FIG. 2 and can be contacted by a screw (not shown) together with the sixth contact electrode 8 with an external voltage/current source in the ninth contacting region 23. In the seventh contacting region 21 and in the eighth contacting region 22, no contact electrodes are contacted.

In each of the contacting regions 15, 16, 17, 18, 19, 20, 21, 22, 23, the housing 2 in FIG. 2 has a recess formed as a longitudinally extended hole (rectangular in shape), which functions as an ‘elongated hole’, to allow a screw to be guided through the housing 2 through the respective contact electrode 3, 4, 5, 6, 7, 8 with a certain tolerance.

It is essential that in the second configuration mode the same housing 2 can be used as in the first configuration mode (see FIG. 1).

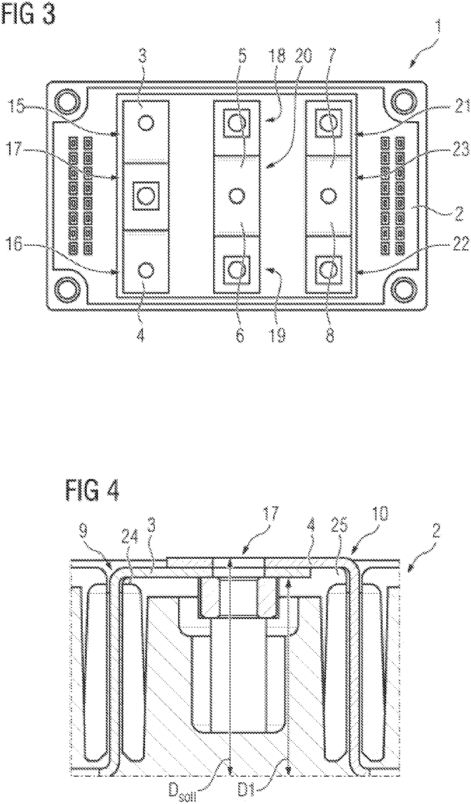

In FIG. 3 a power semiconductor module 1 in accordance with the invention in a third configuration mode is shown in a top view. In FIG. 3, the first contact electrode 3 is bent (upward in FIG. 3) around an edge in the housing 2 in the first contacting region 15 (see FIG. 4) and can be contacted by a screw (not shown) with an external voltage/current source in the first contacting region 15. The second contact electrode 4 is bent downward in FIG. 2 and can be contacted by a screw (not shown) with an external voltage/current source in the second contacting region 16. In the third contacting region 17, no contact electrodes are contacted.

The third contact electrode 5 is bent (downward in FIG. 3) around an edge in the housing 2 in the sixth contacting region 20 (see FIG. 4) and can be contacted by a screw (not shown) with an external voltage/current source in the sixth contacting region 20. The fourth contact electrode 6 is bent upward in FIG. 2 and can be contacted by a screw (not shown) together with the third contact electrode 5 with an external voltage/current source in the third contacting region 20. In the fourth contacting region 18 and in the fifth contacting region 19 no contact electrodes are contacted.

The fifth contact electrode 7 is bent (downward in FIG. 3) around an edge in the housing 2 in the ninth contacting region 23 (see FIG. 4) and can be contacted by a screw (not shown) with an external voltage/current source in the ninth contacting region 23. The sixth contact electrode 8 is bent upward in FIG. 2 and can be contacted by a screw (not shown) together with the fifth contact electrode 7 with an external voltage/current source in the ninth contacting region 23. In the seventh contacting region 21 and in the eighth contacting region 22, no contact electrodes are contacted.

In each of the contacting regions 15, 16, 17, 18, 19, 20, 21, 22, 23, the housing 2 in FIG. 3 has a predefined but not yet pushed through recess in the form of a circular hole to allow a screw to be guided through the housing 2 through the respective contact electrode 3, 4, 5, 6, 7, 8 with a certain tolerance (wherein the housing 2 is pushed through).

It is essential that in the third configuration mode the same housing 2 can be used as in the first and in the second configuration mode (see FIG. 1 and FIG. 2).

In the third configuration mode, the power semiconductor module 1 can, for example, be used for a 3L power semiconductor circuit. In the first contacting region 15, the first contact electrode can be used for a DC voltage connection ‘DC+’, and in the second contacting region 16 the second contact electrode 16 for a DC voltage connection ‘DC-’. In the sixth contacting region 20, an overlaying of the third contact electrode 3 with the fourth contact electrode 4 can be used as a DC voltage midpoint connection ‘DCM’. An overlaying of the fifth contact electrode 5 with the sixth contact electrode 6 in the ninth contacting region 23 can be used as an AC voltage connection ‘AC’.

FIG. 4 shows a cross section of a housing 2 of a power semiconductor module 1 in accordance with the invention. A first contact electrode 3 and a second contact electrode 4 are identifiable. The two contact electrodes 3, 4 are guided outward through the housing 2 and bent around an edge 24, 25 respectively. The edges 24, 25 each have a rounding to facilitate bending of the contact electrodes 3, 4 around the edges 24, 25. In a region of the recesses 9, 10, through which the contact electrodes 3, 4 are guided outward through the housing 2, these are surrounded by an electrically insulating material. Both contact electrodes 3, 4 are thereby guided in the recesses 9, 10, whereby the forces resulting from the bending can be easily absorbed without damaging a connection between the contact electrodes 3, 4 and the power semiconductor circuit.

In the third contacting region 17, in which the first and second contact electrodes 3, 4 can be contacted one above the other with the housing 2, a thickness D1 of the housing 2 is configured such that this corresponds to a target thickness Dtarget of the housing 2 minus the sum of the cross sections of the two contact electrodes 3, 4. In other words, the housing 2 is recessed in the third contacting region 17 such that an arrangement of both contact electrodes 3, 4 in this region results in an effective thickness of the housing 2, which this should uniformly outwardly have. Accordingly, the first contacting region 15 and the second contacting region 16 are each recessed by a section of the first contact electrode 3 or the second contact electrode 4 with respect to the target thickness Dtarget (not shown in FIG. 4).

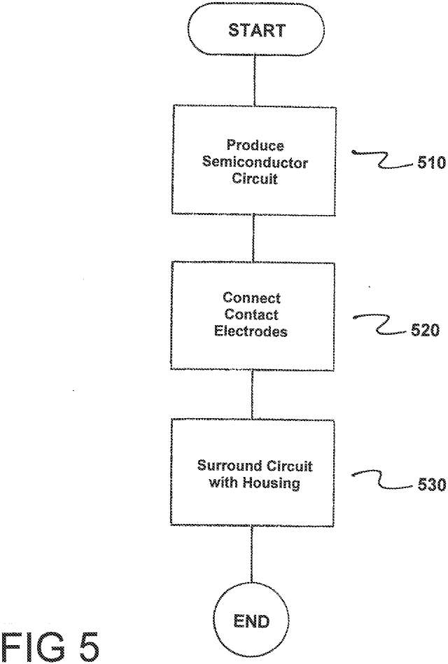

FIG. 5 is a flowchart of the method for producing a power semiconductor module 1. The method comprises a) producing a power semiconductor circuit, as indicated in step 510. Next, b) a first contact electrode 3 and a second contact electrode 4 are connected with the power semiconductor circuit via soldering or ultrasound welding, as indicated in step 520.

Next, c) the power semiconductor circuit surrounding at least partially with a housing 2, as indicated in step 530. Here, the first and second contact electrodes 3, 4 are each guided outward through the housing 2 through a recess 9, 10 in the housing 2, and the housing 2 includes a first contacting region 15, a second contacting region 16, and a third contacting region 17.

In accordance with the invention, the first contact electrode 3 is bent and contacted with an external voltage/current source in the first contacting region 15 or in the third contacting region 17, wherein the second contact electrode 4 is bent and contacted with an external voltage/current source in the second contacting region 16 or in the third contacting region 17, and each contact occurs aided by a screw.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1-12. (canceled)

13. A power semiconductor module, comprising:
a power semiconductor circuit including a first contact electrode and a second contact electrode which are each electrically conductively connected to the power semiconductor circuit; and
a housing which at least partially surrounds the power semiconductor circuit, the first and second contact electrodes each being guided outward through the housing through a recess in the housing;
wherein the housing includes a first contacting region, a second contacting region and a third contacting region;
wherein the first contact electrode is contactable in the first contacting region and the second contact electrode is contactable in the second contacting region, the first contact electrode and the second contact electrode can be contactable together in the third contacting region;
wherein the housing includes a recess in each of the contacting regions into which a threaded part is inserted, wherein the recesses, and the threaded part, are configured to receive a screw to contact the contact electrodes in each contacting region with an external voltage/current source, on an outer face of the housing; and
wherein the contact electrodes also have a recess for receiving the screw.

14. The power semiconductor module as claimed in claim 13, wherein the power semiconductor module has an integer multiple of first and second contact electrodes and an integer multiple of three contacting regions; and wherein the contact electrodes and the contacting regions are each configured on the housing according to claim 13.

15. The power semiconductor module as claimed in claim 13, wherein the first contact electrode and the second contact electrode are each bendable around two edges of the housing.

16. The power semiconductor module as claimed in claim 14, wherein the first contact electrode and the second contact electrode are each bendable around two edges of the housing.

17. The power semiconductor module as claimed in claim 15, wherein the edges have a rounding to facilitate bending of the contact electrodes.

18. The power semiconductor module as claimed in claim 13, wherein the contact electrodes in a region of the recesses, through which the contact electrodes are guided outward through the housing, are surrounded by an electrically insulating material.

19. The power semiconductor module as claimed in claim 18, wherein the recesses in the contact electrodes are each configured as a longitudinally extended hole.

20. The power semiconductor module as claimed in claim 13, wherein the housing in the third contacting region, in which the first contact electrode and the second contact electrode is contactable, has a smaller thickness than in the first contacting region and in the second contacting region.

21. The power semiconductor module according to claim 13, wherein the housing in the first contacting region has a thickness which differs from a thickness in the second contacting region.

22. The power semiconductor module according to claim 13, wherein the housing is configured substantially rectangular with four large-area longitudinal sides and two smaller-area end faces; and wherein the contacting regions are located in a central region of one side of the four large-area longitudinal sides.

23. A housing for a power semiconductor module, wherein the power semiconductor module is configured according to one of claim 13.

24. A power semiconductor module system with a plurality of power semiconductor modules, configured according to claim 13.

25. A method for producing a power semiconductor module, comprising:
a) producing a power semiconductor circuit;
b) connecting a first contact electrode and a second contact electrode with the power semiconductor circuit via soldering or ultrasound welding; and
c) surrounding at least partially the power semiconductor circuit with a housing, the first and second contact electrodes each being guided outward through the housing through a recess in the housing, and the housing including a first contacting region, a second contacting region, and a third contacting region;
wherein the first contact electrode is bent and contacted with an external voltage/current source in the first contacting region or in the third contacting region;
wherein the second contact electrode is bent and contacted with an external voltage/current source in the second contacting region or in the third contacting region; and
wherein each contact occurs aided by a screw.
